(19) United States
(12) Patent Application Publication
(10) Pub. No.: US 2026/0358700 A1
(43) Pub. Date: Nov. 12, 2026

(54) SYSTEM FOR MASK INSPECTION, IMAGE RECORDING DEVICE AND METHOD FOR OPERATING A CHARGE COLLECTING SENSOR

(71) Applicant: Carl Zeiss SMT GmbH, Oberkochen (DE)

(72) Inventors: Maximilian Albert, Heidenheim (DE); Julian Becker, Aalen (DE); Ecaterina Bodnariuc, Berlin (DE); Renzo Capelli, Heidenheim (DE); Dennis Glaeser, Berlin (DE); Klaus Gwosch, Aalen (DE); Johann Irnstetter, Heidenheim (DE); Friedjof Heuck, Stuttgart (DE); Daniel Weller, Erlangen (DE)

(21) Appl. No.: 19/671,672

(22) Filed: May 8, 2026

(30) Foreign Application Priority Data
May 12, 2025 (DE) 102025118155.1

(51) Int. Cl. G03F 1/84; H04N 25/626; H04N 25/71

(52) U.S. Cl. CPC G03F 1/84; H04N 25/626; H04N 25/71

(57) ABSTRACT

The invention relates to a system for mask inspection, an image recording device and a method for operating a charge collecting sensor. A system for mask inspection comprises an illumination system, a projection lens, and an image recording device comprising a charge collecting sensor and an evaluation and processing unit, wherein an object field situated in an object plane and illuminated by way of the illumination system is imaged by the projection lens onto an image field situated in an image plane (IP), wherein the charge collecting sensor is situated in the image plane (IP), wherein the evaluation and processing unit, in order to perform a correction of measured signals provided by the charge collecting sensor, is configured to determine a ghost signal being characteristic for a ghosting effect of the charge collecting sensor based on parameters being characteristic for a trapping or de-trapping of electrical charges in a sensor material of the charge collecting sensor and on a tracking of an occupation of traps in the sensor material by electrical charges during operation of the charge collecting sensor, and to provide a corrected signal based on a measured signal of the charge collecting sensor and on the ghost signal.

### CROSS-REFERENCE TO RELATED APPLICATION

This application claims priority of German Patent Application DE 10 2025 118 155.1, filed on May 12, 2025. The content of this application is hereby incorporated by reference.

### TECHNICAL FIELD

The invention relates to a system for mask inspection, an image recording device and a method for operating a charge collecting sensor.

### BACKGROUND

Microlithography is used for producing microstructured components, such as integrated circuits or liquid crystal displays (LCDs), for example. The microlithography process is carried out in a so-called projection exposure apparatus comprising an illumination device and a projection lens. In this case, the image of a mask (=reticle) illuminated using the illumination device is projected by the projection lens onto a substrate (e.g., a silicon wafer) that is coated with a light-sensitive layer (photoresist) and arranged in the image plane of the projection lens, in order to transfer the mask structure to the light-sensitive coating of the substrate.

In order to test the mask for sufficient imaging capability before it is used in mass production, specifically under conditions which are similar to those really present in the projection exposure apparatus, it is known to use systems for mask inspection which in turn comprise an illumination system and a projection lens, the illuminated region of the mask being imaged onto a charge coupled device (CCD) sensor by use of the projection lens.

Providing a system for mask inspection which enables an accurate prediction of the imaging result that results from the lithography process on the wafer is a demanding challenge, particularly in the inspection of masks designed for operation in the extreme ultraviolet (“EUV”, i.e., at wavelengths of less than 30 nm, in particular less than 15 nm).

In particular, a problem occurring in practice, inter alia, is that exposures of the CCD sensor with EUV light show residual presence of previous exposures of the CCD sensor, which is also called “ghost image” or “ghost signal”. This ghost signal being visible in subsequent exposures is a limiting issue for the performance of the CCD sensor or a system for mask inspection in which the same is used.

For prior art reference is made merely by way of example to US 2009/278971 A1 as well as to the publications A. Rest et al.: “Residual images in charged-coupled device detectors”, Rev. Sci. Instrum., Vol. 73, No. 5, May 2002, pages 2028-2032 and Barry E. Burke: “Dynamic Suppression of Interface-State Dark Current in Buried-Channel CCD's”, IEEE Transactions of Electron Devices, Vol. 38, No. 2, February 1991, pages 285-290.

### SUMMARY

Against the background above, it is a general aspect of the present invention to provide a system for mask inspection, an image recording device and a method for operating a charge collecting sensor while at least partly avoiding the problems described above.

This general aspect is achieved according to the features of the independent claims.

In accordance with one aspect, the invention relates to a system for mask inspection, comprising
an illumination system,
a projection lens, and
an image recording device comprising a charge collecting sensor and an evaluation and processing unit,
wherein an object field situated in an object plane and illuminated by way of the illumination system is imaged by the projection lens onto an image field situated in an image plane, wherein the charge collecting sensor is situated in the image plane,
   wherein the evaluation and processing unit, in order to perform a correction of measured signals provided by the charge collecting sensor, is configured
to determine a ghost signal being characteristic for a ghosting effect of the charge collecting sensor based on parameters being characteristic for a trapping or de-trapping of electrical charges in a sensor material of the charge collecting sensor and on a tracking of an occupation of traps in the sensor material by electrical charges during operation of the charge collecting sensor; and
to provide a corrected signal based on a measured signal of the charge collecting sensor and on the ghost signal.

The invention is particularly based on the concept to track, during operation of the charge collecting sensor (e.g., a CCD sensor), an occupation of traps by electrical charges in the sensor material due to a ghosting effect and to use knowledge about fundamental properties of the sensor material in order to correct the measured signals of the charge collecting sensor accordingly.

In particular, the inventors concluded based on careful investigations and exclusion of other causes that the observed effect described in the introduction, i.e., the effect that exposures of the charge collecting sensor (e.g., CCD sensor) with (e.g., EUV-) light show residual presence of previous exposures or structures, respectively, is consistent with the behavior of electron traps in the (e.g., silicon) bulk material of the charge collecting sensor or CCD sensor, respectively. Furthermore, the inventors found by investigations that the properties of these traps are consistent with either contamination with copper (Cu) or boron-vacancy complexes (B-V). Both types of traps originate in an epitaxial silicon layer (“EPI”) coated substrate wafer in the manufacturing process, namely by migrating from the substrate wafer into the EPI before the substrate wafer is completely removed during further device processing.

In accordance with one embodiment the evaluation and processing unit is configured to determine the parameters based on a model describing a ghosting effect in the charge collecting sensor.

In accordance with one embodiment the mask is designed for operation in reflection at an operating wavelength of less than 30 nm and is intended to be illuminated in a lithography process in a projection exposure apparatus for exposing a wafer.

In accordance with one embodiment the parameters comprise at least one of
a trapping probability (p₀) for an electrical charge in the sensor material,
a decay time (τ) of an occupation of traps in the sensor material, and
a maximum number of charges (nₘₐₓ) that can be trapped in the sensor material.

In accordance with one embodiment the charge collecting sensor is an image sensor, in particular a CCD sensor.

The invention further relates to an image recording device for a metrology system, in particular for a system for mask inspection having the features described above, comprising
a charge collecting sensor; and
an evaluation and processing unit configured to perform a correction of measured signals provided by the charge collecting sensor,
   wherein the evaluation and processing unit is configured
to determine a ghost signal being characteristic for a ghosting effect of the charge collecting sensor based on parameters being characteristic for a trapping or de-trapping of electrical charges in a sensor material of the charge collecting sensor and on a tracking of an occupation of traps in the sensor material by electrical charges during operation of the charge collecting sensor; and
to provide a corrected signal based on a measured signal of the charge collecting sensor and on the ghost signal.

In accordance with one embodiment the evaluation and processing unit is configured to determine the parameters based on a model describing a ghosting effect in the charge collecting sensor.

For further advantages and advantageous configurations of the image recording device and of the system for mask inspection, reference is made to the embodiments in association with the method according to the invention as described in the following.

The invention further relates to a method for operating a charge collecting sensor, in particular in a system for mask inspection having the features described above, comprising the following steps:
a) Determining parameters of the charge collecting sensor based on a model describing a ghosting effect in the charge collecting sensor, said parameters being characteristic for a trapping or de-trapping of electrical charges in a sensor material of the charge collecting sensor;
b) Determining a ghost signal being characteristic for a ghosting effect in the charge collecting sensor based on the parameters determined in step a) and on a tracking of an occupation of traps in the sensor material by electrical charges during operation of the charge collecting sensor; and
c) Providing a corrected signal based on a measured signal of the charge collecting sensor and on the ghost signal determined in step b).

In accordance with one embodiment the parameters comprise at least one of
a trapping probability (p₀) for an electrical charge in the sensor material,
a decay time (τ) of an occupation of traps in the sensor material, and
a maximum number of charges (nₘₐₓ) that can be trapped in the sensor material.

In accordance with one embodiment said charge collecting sensor is an image sensor, in particular a CCD sensor.

In accordance with one embodiment step a) of determining parameters of the image sensor or CCD sensor comprises performing a series of measurements of a given sequence of images.

In accordance with one embodiment the sequence of measurements comprises both measurements of bright images being recorded for an illuminated state of the image sensor or

CCD sensor and measurements of dark images being recorded for a non-illuminated state of the image sensor or CCD sensor.

In accordance with one embodiment step b) comprises a simulation of a trap state evolution during operation of the charge collecting sensor.

In accordance with one embodiment the method further comprises the following step:
subjecting the charge collecting sensor to a pre-exposure in which the charge collecting sensor is pre-conditioned with light in order to provide a defined trapping state of electrical charges in the sensor material.

This pre-exposure of the charge collecting sensor can be advantageously realized both in combination with the afore-described algorithmic correction or independently thereof.

The invention further relates to a method for operating a charge collecting sensor, in particular in a system for mask inspection having the features described above, wherein the charge collecting sensor is subjected to a pre-exposure in which the charge collecting sensor is pre-conditioned with light in order to provide a defined trapping state of electrical charges in a sensor material of the charge collecting sensor.

In accordance with one embodiment the method further comprises the step of reducing an operating temperature of the charge collecting sensor to a temperature value lower than −5 °C.

In accordance with one embodiment the charge collecting sensor is operated with light of a wavelength less than 30 nm, in particular less than 15 nm.

The invention further relates to a method for manufacturing of a charge collecting sensor, in particular in a system for mask inspection having the features described above, comprising the following steps:
i. Preparing an active wafer and a support structure;
ii. Mechanically and/or chemically treating the active wafer in order to reduce the overall thickness;
iii. Implanting additional dopants and annealing;
iv. Assembling the charge collecting sensor,
wherein step ii) is extended until the thickness of the active wafer has a value less than 10 μm.

According to this aspect, a mechanical thinning of the sensor material during manufacturing is consciously and purposefully extended (beyond a standard thickness conventionally provided) with the goal to reduce or minimize the maximum number of trapped charges.

Further configurations of the invention can be gathered from the description and the dependent claims.

The invention is explained in greater detail below on the basis of preferred exemplary embodiments with reference to the accompanying drawings.

### BRIEF DESCRIPTION OF DRAWINGS

In the figures:

FIG. 1 shows a schematic illustration of a CCD sensor according to an embodiment of the present invention;

FIG. 2A-3B show schematic sketches of a ghost protocol measurement sequence (FIGS. 2A and 3A) and the corresponding effect of ghosting on measured frames (FIGS. 2B and 3B);

FIG. 4 a flowchart illustrating a calibration which is performed in a method according to an embodiment of the present invention;

FIG. 5 a flowchart illustrating a simulation of a ghost signal which is performed in a method according to an embodiment of the present invention;

FIG. 6 a flowchart illustrating the basic principle of a correction of a measured signal performed in a method according to an embodiment of the present invention;

FIG. 7 shows a schematic illustration of a CCD sensor for elucidating a problem addressed by the invention;

FIG. 8 a flowchart illustrating in a simplified manner a possible process to manufacture a CCD sensor according to an embodiment of the present invention; and

FIG. 9 a schematic illustration of a system for mask inspection that may use a CCD sensor according to the invention.

### DETAILED DESCRIPTION

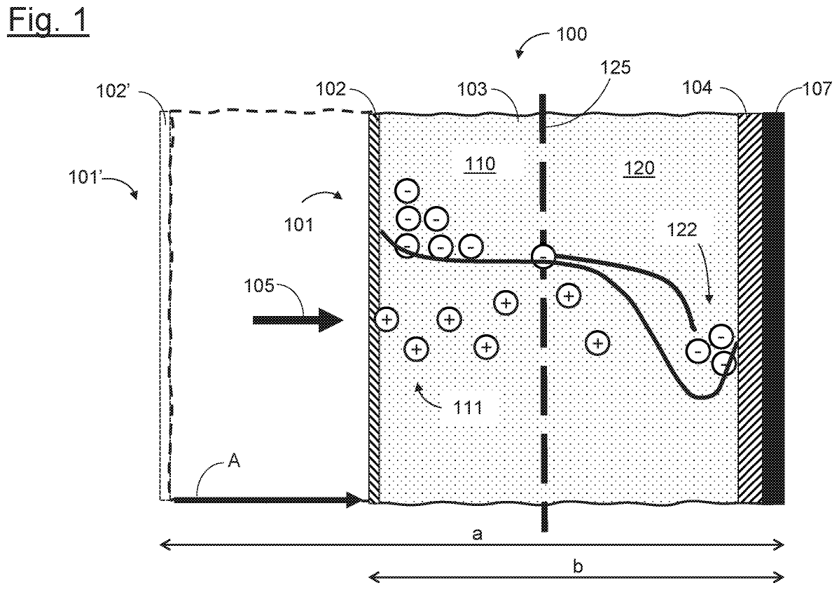

In the following, embodiments of the invention are described with reference to the schematic illustrations in FIGS. 1-9. Although the description is made for on the basis of the exemplary application of the invention to a backside illuminated CCD sensor, the invention is not limited thereto and other application scenarios of a charge collecting sensor or image sensor should also be encompassed by the invention and the disclosure.

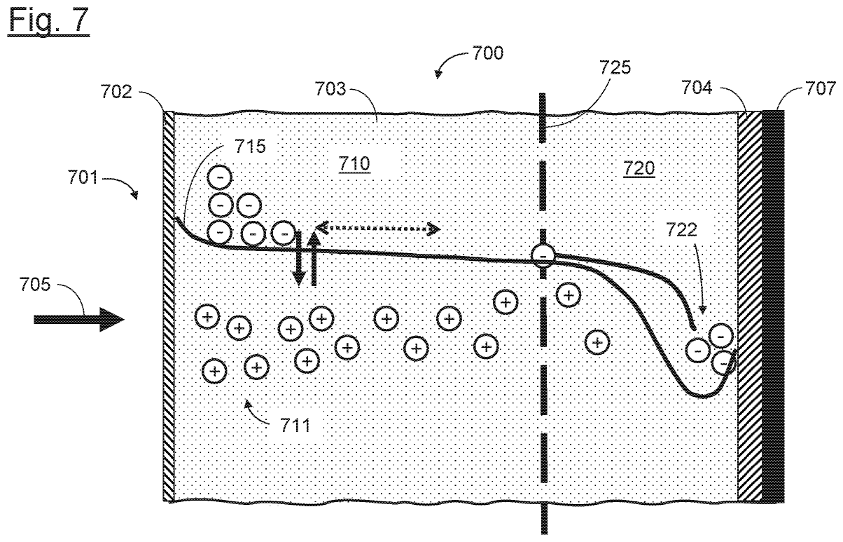

FIG. 7 shows a schematic (and not to scale) illustration of a charge collecting sensor 700 for elucidating a problem addressed by the invention. Here, the charge collecting sensor 700 is a CCD sensor which is illuminated via its backside 701. EUV light 705 (and also visible light) enters into the CCD sensor via an oxide surface layer 702 and creates electron-hole pairs in the silicon bulk material 703. For example, the CCD sensor can have an array of independently addressable sensing elements or pixels. The CCD sensor can have, e.g., thousands, millions, or more, of pixels.

The charge collecting sensor according to the present invention does not necessarily have to be a CCD sensor. For example, the charge-collecting sensor can also be another silicon (Si)-based sensor (e.g. a CMOS-sensor). Furthermore, charge collecting sensors which can be used according to the invention comprise both integrating sensors and photon-counting sensors.

In FIG. 7, electrons (which are mobile) are symbolized by “−” circles, whereas traps (which are fixed in location) are symbolized by “+” circles and indicated with “711”. A potential 715 is engineered such that holes are collected at a backside region (where the light 705 enters) and do not contribute to the measured signal. In the limit of many photons the “initial” distribution of electrons follows an exponential decay with approximately 1 μm decay length. Electrons cannot reach the backside 701 due to the potential wall of potential 715 and diffuse freely in the undepleted region 710 until they reach the depleted region 720 at the transition border 725. Once the electrons/charges reach the depleted region 720, they are pulled into a charge collection well 722 where they are stored until readout. At any time before this readout, these charges can be trapped on a trapping site. In the charge collection well 722, the number of electrons is so large that it is highly likely that the traps are occupied. Since the “de-trapping time” is much larger than the readout and illumination time, these traps will not be visible as a decrease in the charge transfer efficiency (CTE), but rather as a slightly increased dark current and noise signal. In the depleted region 720, the electrons move under the influence of an electric field, so they are in this region only for a very short amount of time which is negligible compared to the diffusion time in the undepleted region 710. In addition, it is known from literature that an electric field can decrease the de-trapping time (also called “field-assisted de-trapping”) by effectively lowering the potential barrier of a trap. In the undepleted region 710, electrons diffuse freely until they reach the depleted region 720 and can be trapped at any time during this process. The expected time for electrons to diffuse across the field free region is proportional to a diffusion constant D and the square of the distance. The diffusion constant varies with one over the square root of the temperature of the sensor, thus is lower at higher temperature. “704” and “707” are indicative of the electric circuitry.

Drift, diffusion, trapping and de-trapping are well known concepts in solid state physics and well documented in literature. In the context of CCD sensors trapping theory, mathematical models and experimental verification by qualification of different CCD sensors, reference is made, e.g., to the publication A. Rest et al.: “Residual images in charged-coupled device detectors”, Rev. Sci. Instrum., Vol. 73, No. 5, May 2002, pages 2028-2032.

Differential equations can be formulated that describe the evolution of the response of the charge collecting sensor 700 as a function of its current state (in particular trap occupation), the input stimulus (in particular the intensity of the incoming signal) and fundamental properties (in particular “trap density”, “trapping probability” and “de-trapping probability”).

### I. Algorithmic Correction

As the observed ghosting effect is consistent with theory, an algorithmic model was built. Measurement data was subsequently fitted to the simulation and fundamental trap parameters could be extracted that are consistent with the root cause described here. As described in the following, a series of measurements was defined (“ghost protocol”) that allows to measure the ghosting properties of a given charge collecting sensor or CCD sensor, respectively, in a quantitative way, e.g., for comparing sensors from different production batches.

This algorithmic correction solution requires that the occupation of the traps in the sensor material is tracked on a per pixel basis and that fundamental material constants, such as “total number of traps”, “trapping probability” and “de-trapping time”, are available on a per pixel basis as well.

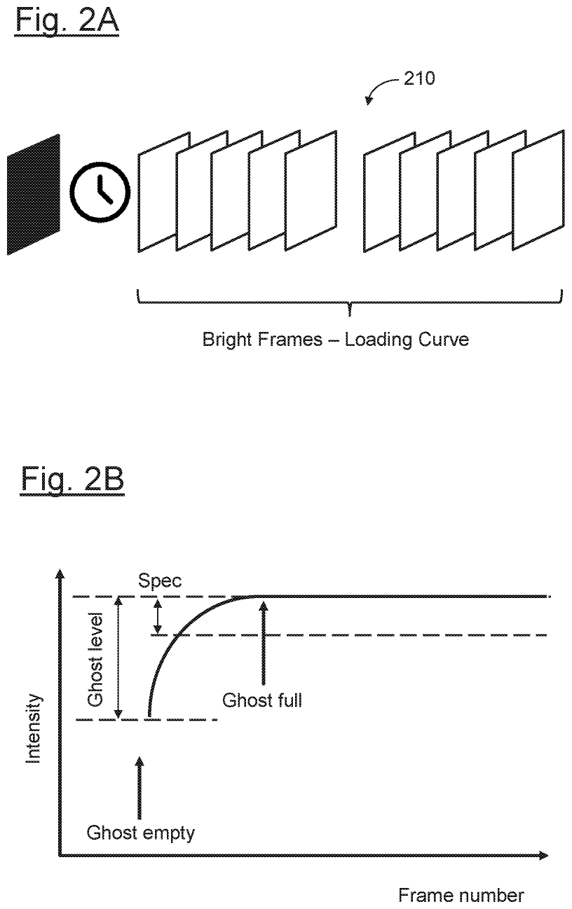

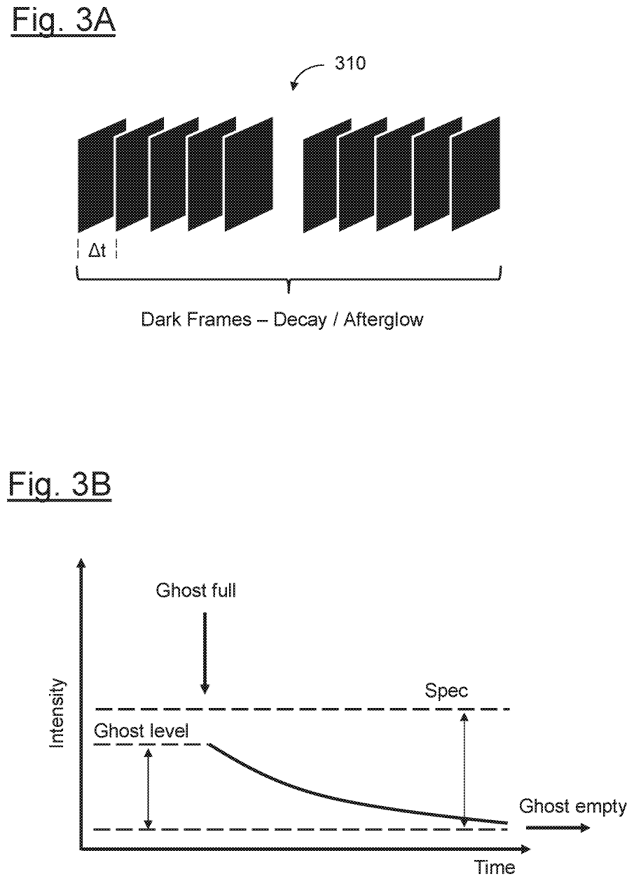

The fundamental material constants can be estimated on a per pixel basis by fitting a model—e.g., the model which is described by equation (1) as specified below—to measurement data, in particular to data acquired with the “ghost protocol” imaging sequence described in the following with reference to FIGS. 2A-2B and FIGS. 3A-3B. The fitting method may, e.g., comprise a method of least squares (LS-fit=“least-square”-fit) or a maximum likelihood fit (“MLE”=maximum likelihood estimation).

FIGS. 2A-2B and FIGS. 3A-3B show schematic sketches of the ghost protocol measurement sequence (FIG. 2A and FIG. 3A) and the corresponding effect of “ghosting” on measured frames (FIG. 2B and FIG. 3B). More specifically, FIG. 2A schematically illustrates the recordation of a plurality of “bright images” 210 being recorded for an illuminated state of the CCD sensor, while FIG. 2B shows the corresponding “loading signal” or “charging curve” (representing the intensity measured on a pixel of the CCD sensor). “Ghost level” in FIG. 2B indicates the “initial deficit” (i.e., the difference between the “real value” of light intensity and the “measured value” of light intensity); “Spec” denotes the maximum allowed deviation (which means that, for a sensor which can be regarded as sufficiently good, the difference between the real value and the measured value is smaller than “Spec”). Once enough charges are loaded into the traps, the deviation becomes effectively zero (i.e., an equilibrium between a trapping of charges and a detrapping of charges is achieved).

FIG. 3A schematically illustrates the recordation of a plurality of “dark images” 310 being recorded for a non-illuminated state of the CCD sensor (i.e., in a state after the afore-mentioned illumination, when all traps in the CCD sensor material are filled and illumination of the CCD sensor is stopped), while FIG. 3B shows the corresponding “decay signal”. The measured intensity is plotted along the vertical axis in FIG. 3B. “Ghost level” in FIG. 3B indicates the initial surplus of charges. Further, as in FIG. 2B, “Spec” denotes the maximum allowed deviation (so for a sufficiently good sensor the difference between measured value and the real value is smaller than “Spec”). Due to the decay an asymptotic approach of the “measured value” to the “real value” is achieved.

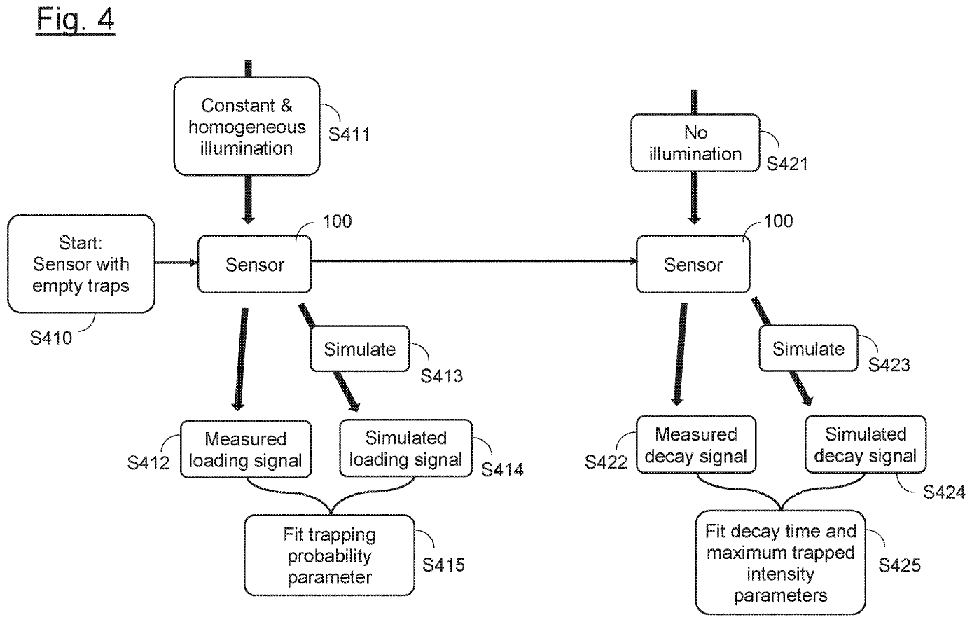

From analytical fits to the measurement data obtained in the measurement sequences which have been described above with respect to FIGS. 2A-2B and FIGS. 3A-3B, fundamental properties (or parameters being characteristic for a trapping or de-trapping of electrical charges in a sensor material of the CCD sensor) can be extracted as illustrated in the flowchart of FIG. 4.

More specifically and as can be gathered from FIG. 4, starting in a state of the CCD Sensor with empty traps (Step S410) and performing a constant and homogeneous illumination S411 of the CCD sensor, the “trapping probability”-parameter is determined in Steps S412-S415. In step S412, measurements are performed to collect data. In step S413, a simulation is performed to predict data thereby obtaining a simulated signal (step S414). The trapping parameters are used for the simulation. An iterative process is performed in step S415 by changing the parameters in the simulation until the difference between the measured signal and the simulated signal is minimized. The fitting may, e.g., comprise a least square fit or a maximum likelihood fit. Then the illumination is stopped and starting from the corresponding state with no illumination (Step S421), the “decay time”-parameter and the “maximum trapped intensity”-parameter (which corresponds to a maximum number of charges nₘₐₓ that can be trapped in the sensor material) are determined in Steps S422-S425.

The respective sets of fit parameters obtained in steps S415 and S425 are different from each other, and both sets are needed for equation (1): More specifically, the parameters obtained in in step S415 comprise the “trapping probability”, whereas the parameters obtained in step S425 comprise the “decay time” and the “maximum trapped intensity” (or number of traps).

According to embodiments of the invention, the parameters “trapping probability”, “decay time” and “maximum trapped intensity” can be determined once during startup and stored for use for many image frames. As signals, e.g., complete images can be sent from the sensor to the evaluation and processing unit for determining the parameters.

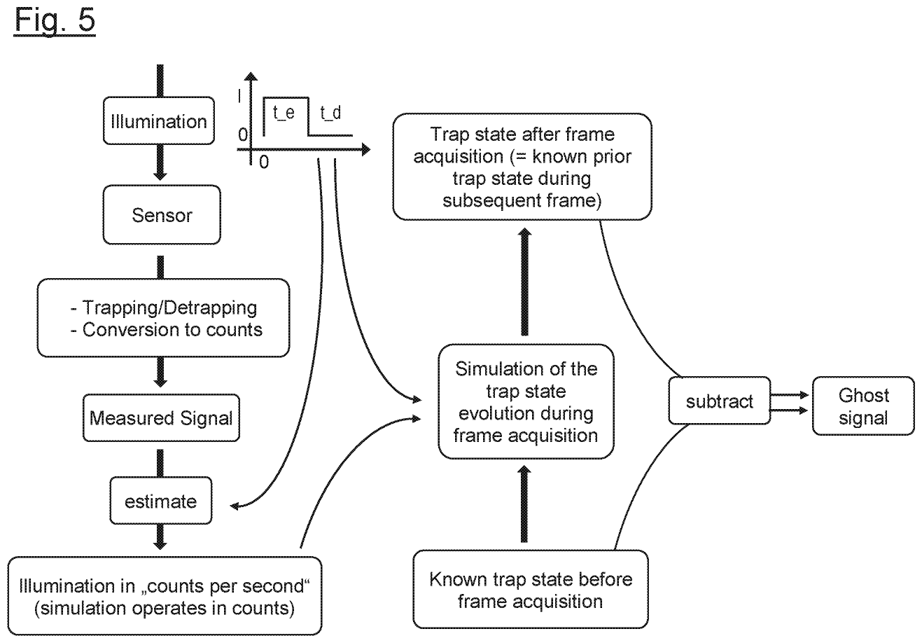

FIG. 5 shows a flowchart illustrating a simulation of a ghost signal which is performed in a method according to an embodiment of the present invention. While the afore-described determination of parameters according to FIG. 4 was performed with a deterministic illumination sequence (according to FIGS. 2A-2B and FIGS. 3A-3B), the simulation of FIG. 5 is performed for the specific measurement scenario in which the CCD sensor is used.

Starting from a known trap state no, an illumination I, and parameters p₀, t and nₘₐₓ (wherein p₀ denotes the initial trapping probability, τ denotes the decay time and nₘₐₓ denotes the maximum number of charges that can be trapped in the sensor material corresponding to the maximum trapped intensity), as illustrated in FIG. 5, the trap state evolution is simulated during frame acquisition step-wise for each duration ΔT in which the illumination I is constant according to equation (1):

$${n}_{1} = {τ}^{′} * [ I * {p}_{0} - {e}^{\frac{Δ T}{{τ}^{′}}} * ( I * {p}_{0} - \frac{{n}_{0}}{{τ}^{′}} ) ] \qquad ( 1 )$$

$$with$$

$${τ}^{′} = 1 / ( I * \frac{{p}_{0}}{{n}_{max}} + \frac{1}{τ} )$$

The left column in FIG. 5 shows the general image acquisition procedure. In the right column in FIG. 5, the block “simulation of the trap state evolution during frame acquisition” receives as input the results which are obtained according to the left column (in particular the illumination in “counts per second”), as well as the “Known trap state before frame acquisition” and the fit parameters that have been determined as described before. The difference between the “trap state after frame acquisition” and the “trap state before frame acquisition” corresponds to the ghost signal (or the difference between the measured signal of intensity and the real value of intensity).

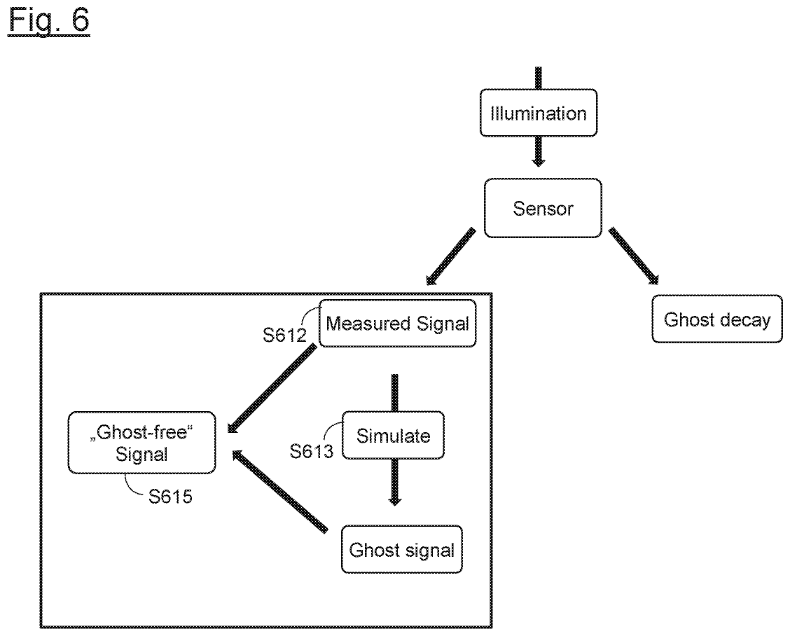

FIG. 6 shows a flowchart illustrating the basic principle of a correction of a measured signal performed in a method according to an embodiment of the present invention. In order to correct the measured signal S612, the “ghosting deficit” of each pixel in each image is calculated (S613) and added to the measured signal S612 (typically after performing other image corrections) to create a corrected image or a “Ghost-free signal” S615. The “ghosting deficit” of each pixel in each image is calculated in step S613 using the afore-described steps in FIG. 5; in particular the parameter values n₀, I, p₀, τ and nₘₐₓ based on equation (1) are determined as described with respect to FIG. 4. The branch “Ghost decay” on the right side of the figure is exemplary for the ghost image that is present in absence of illumination due to decay of trapped charges.

The disclosure comprises further embodiments of a method of operating a CCD sensor which are described in the following. These embodiments can both be realized in combination with the afore-described algorithmic correction according to FIGS. 4-6 or independently thereof.

### II. Pre-Exposure Conditioning of the CCD Sensor

According to an embodiment, which can both be realized in combination with the afore-described algorithmic correction or independently thereof, the method of operating a CCD sensor further comprises the step of subjecting the CCD sensor to a pre-exposure conditioning in which the sensor is uniformly illuminated with EUV-light.

As described previously as root cause, there is a finite number of traps in each pixel and only unoccupied traps contribute to the “bright ghost”, which is the limiting effect under our operating conditions. Since trapping and de-trapping follow different dynamics and the de-trapping time constant under our operating condition is on the order of several tens of seconds there is a certain time window where the traps are sufficiently filled that the remaining unoccupied traps cannot contribute to a ghosting that is significant enough to violate the ghosting specification (maximum tolerable ghost level). This time window can be called “saturation” of the traps. By performing the above-mentioned pre-exposure conditioning, the CCD sensor is brought into saturation by exposure with uniform (EUV-) illumination before the useful measurement is made.

During pre-exposure conditioning either the entire sensor or only a portion of the sensor may be exposed to the EUV illumination. The intensity of the EUV light used for pre-exposure conditioning should be sufficient in order to occupy most traps. Typically that is achieved by illuminating the CCD with a dose of light equal to or exceeding the well depth of the CCD. The pre-exposure conditioning does not have a negative impact on the image acquisition since the collection well in the CCD is cleared before each acquisition. This is implemented by acquiring images and discarding them during the acquisition cycle. The pre-exposure conditioning reduces bright ghost only in the pre-conditioned (previously illuminated) areas; it does not reduce the dark ghost (which is however not limiting in the envisaged application scenario). An alternative to the EUV exposure would be to bring a dedicated light-source into the system, which could have a different spectral range to reduce the number of needed image acquisitions for trap saturation.

### III. Mechanical Treatment of the CCD Sensor During Manufacturing

According to a further embodiment, which can both be realized in combination with the afore-described algorithmic correction or independently thereof, a mechanical treatment of the CCD sensor during its manufacturing process is performed in order to reduce the sensor thickness (i.e., an additional “thinning” of the sensor material of the CCD sensor.) In other words, a mechanical thinning of the sensor material during manufacturing is consciously and purposefully extended (beyond a standard thickness conventionally provided) with the goal to reduce or minimize the maximum number of trapped charges.

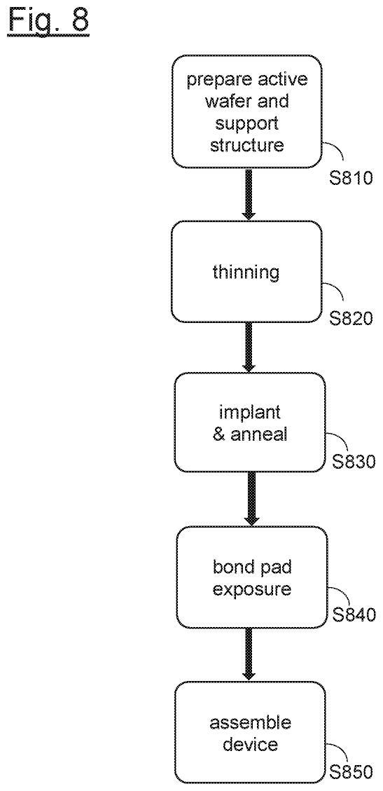

FIG. 8 shows, in a simplified manner, a flowchart illustrating a possible process to manufacture a CCD sensor according to an embodiment of the present invention. FIG. 1 shows a schematic illustration of a charge collecting sensor 100 (with components or regions being analogously to FIG. 7 being denoted with “100+x”-reference signs instead of “700+x”-reference signs).

As schematically illustrated in FIG. 1, the thickness can be reduced from a value “a” (which may, e.g., be roughly 13 μm) to a smaller value “b” (which may, e.g., be roughly 8 μm), as symbolized by arrow “A”. With reference to FIG. 8, this thickness reduction is done during step S820 (“thinning”, which can, e.g., comprise etching, mechanically polishing or lapping) and after preparation of the active wafer (comprising, e.g., electric circuitry on an EPI-layer) and a support structure (e.g., silicon wafer) in step S810. According to preferred embodiments, the thinning reduces the thickness to a value in the range of 6 μm to 10 μm.

Afterwards, standard steps for CCD sensor preparation which are well-known to a person skilled in the art are performed, which (under omission of details) comprise an “implant & anneal”-step (step S830), “bond pad exposure” (step S840) and “assemble device” (step S850). In the “implant & anneal”-step (step S830), additional doping atoms are injected and the oxide layer 102 or 702, respectively, is formed by annealing.

In the afore-mentioned aspect of an additional “thinning” of the sensor material of the charge collecting sensor, the invention makes use of the fact that an intended operation use of the charge collecting sensor with EUV principally allows such a reduction of thickness of the charge collecting sensor which still achieving a sufficient detection efficiency, since the EUV light is already absorbed within a relatively short penetration depth of roughly 1 μm (so the above-mentioned reduction of thickness of the charge collecting sensor does not lead to a deterioration of detection efficiency).

The goal of the afore-mentioned optimization is to reduce the amount of charge carriers trapped at relevant operating conditions. This embodiment is based on the consideration that—in addition to a lower number of overall traps—a reduction of total thickness of undepleted silicon shows major potential for ghost reduction. This is mainly due to the fact that charge carriers are created with an attenuation length of approximately one micrometer, i.e., close to the surface. These charge carriers then have to reach the collection well (depleted silicon) in order to generate a useful signal. The charge transport in the undepleted bulk happens by diffusion only, since there is no electric field. As diffusion is a stochastic process, the expected time for a charge carrier to reach the collection well is proportional to the square of the distance traveled. During this diffusion time, the charge carriers are susceptible to trapping, hence a shorter diffusion distance, and thereby diffusion time. It is expected to result in a lower probability of capturing a charge carrier. On top of this, the number of traps, which is proportional to the ghost level, can be reduced. Traps in the collection well are continuously exposed to the collected dark current and therefore are always in saturation. Since the decay time of these traps is much larger than the typical integration or line shift time, their charging and discharging is not observable under the used operating conditions.

### IV. Reduced Operating Temperature of the CCD Sensor

According to a further embodiment, which can both be realized in combination with the afore-described algorithmic correction or independently thereof, the method of operating a charge collecting sensor further comprises the step of reducing the operating temperature of the charge collecting sensor to a temperature value lower than −5 °C.

This embodiment is based on the consideration that the decay constant depends exponentially on negative inverse temperature, thus colder temperatures exhibit larger decay constants. The approach used in the pre-exposure conditioning (see above section II.) can be further optimized at lower temperatures. Essentially the pre-conditioning by uniform EUV illumination is valid for longer times, allowing to reduce the number of pre-conditioning exposures in the overall acquisition cycle and increasing the run rate of the system with respect to running the system at the current temperature. As a function of several input parameters, especially the desired “retention time”, acceptable ghost level, total number of traps, capture probability and decay time a particularly appropriate sensor temperature can be estimated to be in the range of −5 °C to −12 °C. For reducing the sensor temperature, a Peltier element can be used which is attached with its cold side to the sensor and which is attached with its hot side to a liquid-cooled heat sink. Current and voltage of the Peltier element may be controlled using a standard controller.

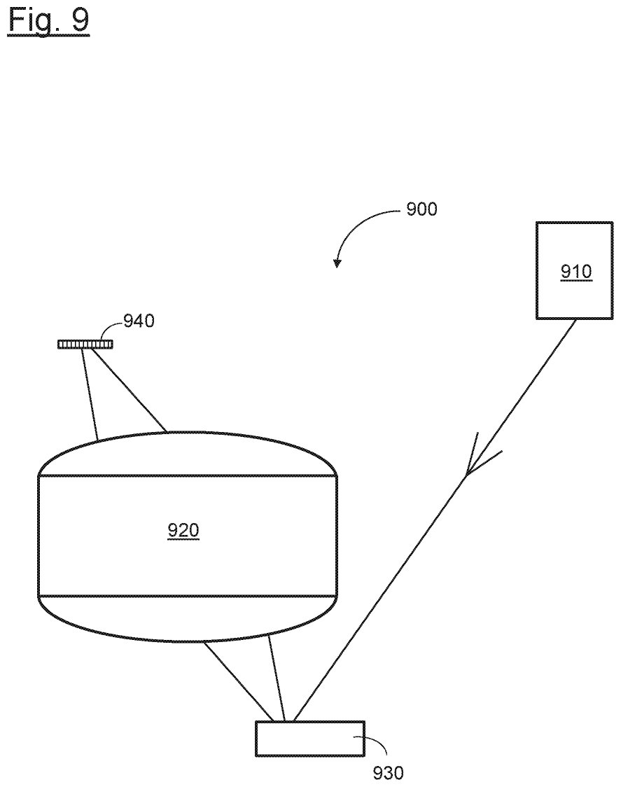

As is illustrated merely schematically in FIG. 9, a system for mask inspection 900 that may use a CCD sensor according to the invention comprises an illumination system 910 and a projection lens 920, wherein light from a light source (not illustrated in FIG. 9) enters the illumination system 910 and is incident on a mask 930 arranged in the object plane of the projection lens 920, and wherein the illuminated region of the mask 930 is imaged onto a sensor arrangement 940 by way of the projection lens 920. Mask inspection systems of this kind are, e.g., known from DE 10 2022 133 829 A1 and US 2025/0298324, filed on Jun. 9, 2025; the contents of the above applications are herein incorporated by reference. In some implementations, the illumination system 910 can include one or more optical elements, such as one or more lenses, mirrors, stops, and/or filters that process and direct the light from the light source to the mask 930. In some implementations, the projection lens 920 can include one or more optical elements, such as one or more lenses and/or mirrors that process and direct the light from the mask 930 to the sensor arrangement 940. In examples where an EUV light source is used, the illumination system 910 can include one or more EUV mirrors, stops, and/or filters that process and direct the EUV light from the EUV light source to the mask 930; the projection lens 920 can include one or more EUV mirrors that process and direct the EUV light from the mask 930 to the sensor arrangement 940. In order to make a prediction of the imaging result attained with a mask when carrying out the lithography process in a projection exposure apparatus, firstly an intensity distribution obtained for the mask in the device for mask inspection of FIG. 9 by use of the sensor arrangement 940 is measured. A CCD sensor which is operated according to the present invention as it has been described before with reference to FIGS. 1-7 can be used in the image plane (IP) as sensor arrangement 940.

In some implementations, the processing of data described above, such as determining parameters of the charge collecting sensor, determining a ghost signal based on the parameters, determining a corrected signal based on a measured signal and the ghost signal, simulation of a trap state evolution, can be performed by an evaluation and processing unit, which can include one or more processing devices. Each processing device can include one or more processor cores, and each processor core can include logic circuitry for processing data. The evaluation and processing unit can include, e.g., one or more central processing units (CPUs), graphics processing units (GPUs), and/or tensor processing units (TPUs). For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, the evaluation and processing unit can include one or more computers, each computer can include one or more data processors for processing data. The one or more machine-readable hardware storage devices can store one or more computer programs including instructions that when executed by the one or more computers cause the one or more computers to carry out the processes described above. The one or more processing devices can include one or more input devices, such as a keyboard, a mouse, a touchpad, and/or a voice command input module, and one or more output devices, such as a display, and/or an audio speaker.

In some implementations, the one or more processing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

The invention can also be used to inspect samples other than masks, such as wafers.

Furthermore, the sample can also be an arbitrary microstructured or nanostructured component or a component from the field of microelectronics or nanotechnology; furthermore, the sample can include a transmissive or a reflective photomask and/or a template for nanoimprint technology; the sample can also include an integrated circuit, a microelectromechanical system (MEMS) and/or a photonic integrated circuit.

Even though the invention has been described on the basis of specific embodiments, numerous variations and alternative embodiments are evident to a person skilled in the art, e.g., through combination and/or exchange of features of individual embodiments. Accordingly, it goes without saying for a person skilled in the art that such variations and alternative embodiments are concomitantly encompassed by the present invention, and the scope of the invention is restricted only within the meaning of the appended patent claims and the equivalents thereof.

The present invention further comprises the aspects defined in the following clauses, which form part of the present description but are not claims.
1. Method for operating a charge collecting sensor, comprising the following steps:
a) Determining parameters of the charge collecting sensor based on a model describing a ghosting effect in the charge collecting sensor, said parameters being characteristic for a trapping or de-trapping of electrical charges in a sensor material of the charge collecting sensor;
b) Determining a ghost signal being characteristic for a ghosting effect in the charge collecting sensor based on the parameters determined in step a) and on a tracking of an occupation of traps in the sensor material by electrical charges during operation of the charge collecting sensor; and
c) Providing a corrected signal based on a measured signal of the charge collecting sensor and on the ghost signal determined in step b).
2. Method according to clause 1, characterized in that the parameters comprise at least one of a trapping probability (p₀) for an electrical charge in the sensor material, a decay time (τ) of an occupation of traps in the sensor material, and a maximum number of charges (nₘₐₓ) that can be trapped in the sensor material.
3. Method according to clause 1 or 2, characterized in that said charge collecting sensor is an image sensor, in particular a CCD sensor.
4. Method according to clause 3, characterized in that step a) of determining parameters of the image sensor or CCD sensor comprises performing a series of measurements of a given sequence of images.
5. Method according to clause 4, characterized in that the sequence of measurements comprises both measurements of bright images being recorded for an illuminated state of the image sensor or CCD sensor and measurements of dark images being recorded for a non-illuminated state of the image sensor or CCD sensor.
6. Method according to any one of the preceding clauses, characterized in that step b) comprises a simulation of a trap state evolution during operation of the charge collecting sensor.
7. Method according to any one of the preceding clauses, characterized in that it further comprises the following step:
   subjecting the charge collecting sensor to a pre-exposure in which the charge collecting sensor is pre-conditioned with light in order to provide a defined trapping state of electrical charges in the sensor material.
8. Method for operating a charge collecting sensor, characterized in that the charge collecting sensor is subjected to a pre-exposure in which the charge collecting sensor is pre-conditioned with light in order to provide a defined trapping state of electrical charges in a sensor material of the charge collecting sensor.
9. Method according to any one of the preceding clauses, characterized in that it further comprises the step of reducing an operating temperature of the charge collecting sensor to a temperature value lower than −5 °C.
10. Method according to any one of the preceding clauses, characterized in that the charge collecting sensor is operated with light of a wavelength less than 30 nm, in particular less than 15 nm.
11. Method for manufacturing of a charge collecting sensor, comprising the following steps:
i. Preparing an active wafer and a support structure;
ii. Mechanically and/or chemically treating the active wafer in order to reduce the overall thickness;
iii. Implanting additional dopants and annealing;
iv. Assembling the charge collecting sensor, characterized in that
said step ii) is extended until the thickness of the active wafer has a value less than 10 μm.
12. Image recording device for a metrology system, comprising
   a charge collecting sensor; and
   an evaluation and processing unit configured to perform a correction of measured signals provided by the charge collecting sensor, characterized in that said evaluation and processing unit is configured to
   determine a ghost signal being characteristic for a ghosting effect of the charge collecting sensor based on parameters being characteristic for a trapping or de-trapping of electrical charges in a sensor material of the charge collecting sensor and on a tracking of an occupation of traps in the sensor material by electrical charges during operation of the charge collecting sensor; and
   provide a corrected signal based on a measured signal of the charge collecting sensor and on the ghost signal.
13. Image recording device according to clause 12, characterized in that the evaluation and processing unit is configured to determine the parameters based on a model describing a ghosting effect in the charge collecting sensor.
14. System for mask inspection, comprising
   an illumination system,
   a projection lens, and
   an image recording device according to clause 12 or 13 comprising a CCD sensor and an evaluation and processing unit,
wherein an object field situated in an object plane and illuminated by way of the illumination system is imaged by the projection lens onto an image field situated in an image plane, wherein the CCD sensor is situated in the image plane.
15. System for mask inspection according to clause 14, wherein the mask is designed for operation in reflection at an operating wavelength of less than 30 nm and is intended to be illuminated in a lithography process in a projection exposure apparatus for exposing a wafer.

What is claimed is:

1. A system for mask inspection, comprising
an illumination system,
a projection lens, and
an image recording device comprising a charge collecting sensor and an evaluation and processing unit,
wherein an object field situated in an object plane and illuminated by way of the illumination system is imaged by the projection lens onto an image field situated in an image plane, wherein the charge collecting sensor is situated in the image plane,
wherein the evaluation and processing unit, in order to perform a correction of measured signals provided by the charge collecting sensor, is configured
to determine a ghost signal being characteristic for a ghosting effect of the charge collecting sensor based on parameters being characteristic for a trapping or de-trapping of electrical charges in a sensor material of the charge collecting sensor and on a tracking of an occupation of traps in the sensor material by electrical charges during operation of the charge collecting sensor; and
to provide a corrected signal based on a measured signal of the charge collecting sensor and on the ghost signal.

2. The system for mask inspection according to claim 1, wherein the evaluation and processing unit is configured to determine the parameters based on a model describing a ghosting effect in the charge collecting sensor.

3. The system for mask inspection according to claim 1, wherein the mask is designed for operation in reflection at an operating wavelength of less than 30 nm and is intended to be illuminated in a lithography process in a projection exposure apparatus for exposing a wafer.

4. The system for mask inspection according to claim 1, wherein the parameters comprise at least one of
a trapping probability for an electrical charge in the sensor material,
a decay time of an occupation of traps in the sensor material, and
a maximum number of charges that can be trapped in the sensor material.

5. The system for mask inspection according to claim 1, wherein the charge collecting sensor is an image sensor, in particular a CCD sensor.

6. An image recording device for a metrology system, in particular for a system for mask inspection according to claim 1, comprising
a charge collecting sensor; and
an evaluation and processing unit configured to perform a correction of measured signals provided by the charge collecting sensor,
wherein the evaluation and processing unit is configured
to determine a ghost signal being characteristic for a ghosting effect of the charge collecting sensor based on parameters being characteristic for a trapping or de-trapping of electrical charges in a sensor material of the charge collecting sensor and on a tracking of an occupation of traps in the sensor material by electrical charges during operation of the charge collecting sensor; and
to provide a corrected signal based on a measured signal of the charge collecting sensor and on the ghost signal.

7. The image recording device according to claim 6, wherein the evaluation and processing unit is configured to determine the parameters based on a model describing a ghosting effect in the charge collecting sensor.

8. A method for operating a charge collecting sensor, in particular in a system for mask inspection according to claim 1, comprising the following steps:
a) determining parameters of the charge collecting sensor based on a model describing a ghosting effect in the charge collecting sensor, said parameters being characteristic for a trapping or de-trapping of electrical charges in a sensor material of the charge collecting sensor;
b) determining a ghost signal being characteristic for a ghosting effect in the charge collecting sensor based on the parameters determined in step a) and on a tracking of an occupation of traps in the sensor material by electrical charges during operation of the charge collecting sensor; and
c) providing a corrected signal based on a measured signal of the charge collecting sensor and on the ghost signal determined in step b).

9. The method according to claim 8, wherein the parameters comprise at least one of
a trapping probability for an electrical charge in the sensor material,
a decay time of an occupation of traps in the sensor material, and
a maximum number of charges that can be trapped in the sensor material.

10. The method according to claim 8, wherein said charge collecting sensor is an image sensor, in particular a CCD sensor.

11. The method according to claim 10, wherein step a) of determining parameters of the image sensor or CCD sensor comprises performing a series of measurements of a given sequence of images.

12. The method according to claim 11, wherein the sequence of measurements comprises both measurements of bright images being recorded for an illuminated state of the image sensor or CCD sensor and measurements of dark images being recorded for a non-illuminated state of the image sensor or CCD sensor.

13. The method according to claim 8, wherein step b) comprises a simulation of a trap state evolution during operation of the charge collecting sensor.

14. The method according to claim 8, further comprising the following step
subjecting the charge collecting sensor to a pre-exposure in which the charge collecting sensor is pre-conditioned with light in order to provide a defined trapping state of electrical charges in the sensor material.

15. A method for operating a charge collecting sensor, in particular in a system for mask inspection according to claim 1, wherein the charge collecting sensor is subjected to a pre-exposure in which the charge collecting sensor is pre-conditioned with light in order to provide a defined trapping state of electrical charges in a sensor material of the charge collecting sensor.

16. The method according to claim 8, further comprising the step of reducing an operating temperature of the charge collecting sensor to a temperature value lower than −5 °C.

17. The method of claim 8, wherein the charge collecting sensor is operated with light of a wavelength less than 30 nm, in particular less than 15 nm.

18. A method for manufacturing of a charge collecting sensor, in particular in a system for mask inspection according to claim 1, comprising the following steps:
i. preparing an active wafer and a support structure;
ii. mechanically and/or chemically treating the active wafer in order to reduce the overall thickness;
iii. implanting additional dopants and annealing;
iv. assembling the charge collecting sensor,
wherein said step ii) is extended until the thickness of the active wafer has a value less than 10 μm.

19. The method of claim 18 wherein the charge collecting sensor comprises a charge-coupled device (CCD) sensor.

20. The method of claim 15, comprising reducing an operating temperature of the charge collecting sensor to a temperature value lower than −5 °C.
